(19) United States
(12) Patent Application Publication
(10) Pub. No.: US 2026/0173854 A1
(43) Pub. Date: Jun. 18, 2026

(54) SEMICONDUCTOR DEVICE INCLUDING WIRING STRUCTURE

(71) Applicant: SAMSUNG ELECTRONICS CO., LTD., Suwon-si (KR)

(72) Inventors: Taehyoung IM, Suwon-si (KR); Taehyung LEE, Suwon-si (KR); Sangkuk KIM, Suwon-si (KR); Hyunchul YOON, Suwon-si (KR); Dokeun LEE, Suwon-si (KR); Jinkwan LEE, Suwon-si (KR)

(73) Assignee: SAMSUNG ELECTRONICS CO., LTD., Suwon-si (KR)

(21) Appl. No.: 19/400,462

(22) Filed: Nov. 25, 2025

(30) Foreign Application Priority Data
Dec. 17, 2024 (KR) 10-2024-0188549

(51) Int. Cl. H01L 23/528; H10B 63/00; H10N 70/00

(52) U.S. Cl. CPC H10W 20/435; H10B 63/24; H10B 63/84; H10N 70/011; H10W 20/43

(57) ABSTRACT

A semiconductor device includes a substrate having a first region and a second region, a first insulating interlayer formed on the substrate, and a lower contact extending through the first insulating interlayer in the second region. A wiring structure including a first conductive pattern is formed on the first insulating interlayer in the first region. A first capping layer covers an upper surface of the first insulating interlayer in the second region, and a second insulating interlayer having a protrusion at an edge of the second region is disposed on the first capping layer. A second capping layer pattern is positioned on the protrusion, and a third insulating interlayer covers the wiring structure and the second insulating interlayer. An upper contact passes through the third insulating interlayer.

### CROSS-REFERENCE TO RELATED APPLICATION

This application claims priority under 35 USC § 119 to Korean Patent Application No. 10-2024-0188549, filed on Dec. 17, 2024, in the Korean Intellectual Property Office KIPO, the contents of which are incorporated by reference herein in their entirety.

### BACKGROUND

Various example embodiments relate to a semiconductor device. Particularly, various example embodiments relate to a to a semiconductor device including a wiring structure and an upper contact.

In the semiconductor device, the wiring structure may be arranged in a first region of a substrate, and an upper contact contacting an upper surface of a lower contact may be arranged in a second region of the substrate. In a process for forming the wiring structure, an upper surface of the lower contact may also be unintentionally etched together. Accordingly, a defect in which the lower contact and the upper contact do not make contact may occur.

### SUMMARY

Various example embodiments provide a semiconductor device including a wiring structure and an upper contact.

Various example embodiments provide a method for manufacturing a semiconductor device including a wiring structure and an upper contact.

According to some example embodiments, there is provided a semiconductor device. The semiconductor device may include a substrate including a first region and a second region; a first insulating interlayer on the first region and the second region of the substrate; a lower contact disposed on the second region of the substrate, the lower contact passing through the first insulating interlayer; a wiring structure disposed on the first insulating interlayer on the first region, the wiring structure including a first conductive pattern; a first capping layer covering an entire upper surface of the first insulating interlayer on the second region; a second insulating interlayer disposed on the first capping layer on the second region, the second insulating interlayer having a protrusion positioned on the first capping layer at an edge of the second region adjacent to the first region; a second capping layer pattern on an upper surface of the protrusion of the second insulating interlayer; a third insulating interlayer covering the first insulating interlayer, the wiring structure, the second capping layer pattern and the second insulating interlayer, and third insulating interlayer having an upper surface higher than an upper surface of the second capping layer pattern; and an upper contact passing through the third insulating interlayer, the second insulating interlayer and the first capping layer on the second region, the upper contact contacting at least a portion of an upper surface of the lower contact.

According to some example embodiments, there is provided a semiconductor device. The semiconductor device may include a substrate including a first region and a second region; a first insulating interlayer disposed on the first region and the second region of the substrate; a first lower contact passing through the first insulating interlayer on the first region; a second lower contact passing through the first insulating interlayer on the second region; wiring structures disposed on a first insulating interlayer of the first region, the wiring structures including a first conductive pattern, a first capping layer pattern, a second capping layer pattern and a third capping layer pattern; a second capping layer covering an entire upper surface of the first insulating interlayer of the second region; a second insulating interlayer disposed on the second capping layer on the second region, the second insulating interlayer having a protrusion positioned on the second capping layer at an edge of the second region adjacent to the first region; a third capping layer pattern on an upper surface of the protrusion of the second insulating interlayer; a third insulating interlayer disposed on the first insulating interlayer, the wiring structures, the third capping layer pattern and the second insulating interlayer, and the third insulating interlayer having an upper surface higher than the upper surfaces of the wiring structures; and an upper contact passing through the third insulating interlayer, the second insulating interlayer and the second capping layer on the second region, and the upper contact contacting at least a portion of an upper surface of the second lower contact.

According to some example embodiments, there is provided a semiconductor device. The semiconductor device may include a substrate including a first region and a second region; a first insulating interlayer on the first region and the second region of the substrate; a lower contact passing through the first insulating interlayer on the second region; a plurality of first conductive patterns disposed on a first insulating interlayer of the first region, each of the plurality of first conductive patterns having a line shape extending in a first direction; memory patterns being spaced apart from each other on each of the first conductive patterns;
a first capping layer covering an entire upper surface of the first insulating interlayer on the second region; a second insulating interlayer disposed on the first capping layer on the second region, the second insulating interlayer having a protrusion on the first capping layer at an edge of the second region adjacent to the first region; a second capping layer pattern on an upper surface of the protrusion of the second insulating interlayer; a third insulating interlayer on the first insulating interlayer and the second insulating interlayer to fill a space between the first conductive patterns and the memory patterns; an upper contact passing through the third insulating interlayer, the second insulating interlayer and the first capping layer on the second region, and at least portion of the upper contact contacting the upper surface of the lower contact; and a second conductive pattern disposed on the memory patterns, the upper contact and the third insulating interlayer, the second conductive pattern contacting the memory patterns and the upper contact.

According to some example embodiments, there is provided a method for manufacturing a semiconductor device. The method for manufacturing the semiconductor device may include forming a first insulating interlayer on a substrate including a first region and a second region, forming a lower contact on the second region of the substrate through the first insulating interlayer, forming a preliminary first conductive pattern and a first preliminary capping layer pattern on the first insulating interlayer on the first region, forming a second capping layer covering an upper surface of the first preliminary capping layer pattern and a sidewall of the preliminary first conductive pattern, patterning the third capping layer, the second capping layer and the preliminary first conductive pattern and etching a portion of the preliminary second insulating interlayer to form a wiring structure including a first conductive pattern, a first capping layer pattern, a second capping layer pattern and a third capping layer pattern on the insulating interlayer of the first region and a second insulating interlayer including a protrusion and the third capping layer pattern on the second capping layer of the second region, forming a third insulating interlayer covering the first insulating interlayer, the wiring structure, the third capping layer pattern, and the second insulating interlayer and having an upper surface higher than an upper surface of the third capping layer pattern, forming an upper contact passing through the third insulating interlayer, the second insulating interlayer and the second capping layer on the second region. at least a portion of the upper contact may contact an upper surface of the lower contact.

In example embodiments, the method may further include a planarization process of an upper portion of the preliminary second insulating interlayer so that an upper surface of the preliminary second insulating interlayer may be coplanar with an upper surface of the second capping layer.

In example embodiments, the first capping layer pattern, the second capping layer pattern and the third capping layer pattern may include silicon nitride.

In example embodiments, the second insulating interlayer may be formed to cover an entire upper surface of the second capping layer on the second region.

In example embodiments, the preliminary first conductive pattern may be formed such that a lower surface of the preliminary first conductive pattern is coplanar with the upper surface of the first insulating interlayer in the second region.

In example embodiments, the lower contact may be formed such that the uppermost surface of the lower contact is coplanar with the lower surface of the second capping layer.

In example embodiments, the method may further include forming a memory pattern contacting the first conductive pattern of the wiring structure, and forming a second conductive pattern contacting an upper surface of the memory pattern and an upper surface of the upper contact.

According to various example embodiments, the semiconductor device may include the first capping layer and the second insulating interlayer disposed on the lower contact in the second region. In addition, the second capping layer pattern may be formed on the protrusion of the second insulating interlayer. An upper surface of the lower contact may be protected by the first capping layer and the second insulating interlayer, so that a vertical level (e.g., height) of the upper surface of the lower contact may not be decreased. Accordingly, a contacting failure between the lower contact and the upper contact may be decreased.

### BRIEF DESCRIPTION OF THE DRAWINGS

Various example embodiments will be more clearly understood from the following detailed description taken in conjunction with the accompanying drawings. FIGS. 1 to 32 represent various non-limiting, example embodiments as described herein.

FIG. 1 is a cross-sectional view of a semiconductor device according to example embodiments;

FIGS. 2 to 19 are cross-sectional views illustrating a method for manufacturing a semiconductor device according to example embodiments;

FIGS. 20 to 22 are cross-sectional views and plan views illustrating semiconductor devices according to example embodiments; and

FIGS. 23 to 32 are cross-sectional views illustrating a method of manufacturing a semiconductor device according to example embodiments.

### DETAILED DESCRIPTION

Hereinafter, various example embodiments will be described in detail with reference to the accompanying drawings.

FIG. 1 is a cross-sectional view of a semiconductor device according to example embodiments.

Referring to FIG. 1, a substrate 100 including a first region A1 and a second region A2 may be provided. The substrate 100 may be a semiconductor substrate.

The first region A1 may be a region for forming wiring structures 190 including a first conductive pattern 122a having a line shape. The second region A2 may be a region for forming an upper contact 202 contacting a second lower contact 112. In the second region A2, the first conductive pattern 122a may not be formed. In example embodiments, the first region A1 may be a cell region, and the second region A2 may be a peripheral region.

A first lower conductive pattern 102 may be formed on the first region A1 of the substrate 100. The first lower conductive pattern 102 may have, e.g., a line shape. In FIG. 1, only one first lower conductive pattern 102 is illustrated, but the invention is not limited thereto, and a plurality of first lower conductive patterns may be arranged on the first region A1.

A second lower conductive pattern 104 may be formed on the second region A2 of the substrate 100. The second lower conductive pattern 104 may have, e.g., a line shape. In FIG. 1, only one second lower conductive pattern 104 is illustrated, but the invention is not limited thereto, and a plurality of second lower conductive patterns may be arranged on the second region A2.

In example embodiments, the first and second lower conductive patterns 102 and 104 may include a metal. For example, the first and second lower conductive patterns 102 and 104 may include the same metal.

A first insulating interlayer 106 may be formed on the substrate 100 to cover the first and second lower conductive patterns 102 and 104. The first insulating interlayer 106 may include, e.g., silicon oxide.

A first lower contact 110 may pass through the first insulating interlayer 106 from an upper surface of the first insulating interlayer 106, and may contact an upper surface of the first lower conductive pattern 102. A second lower contact 112 may pass through the first insulating interlayer 106 from the upper surface of the first insulating interlayer 106, and may contact an upper surface of the second lower conductive pattern 104. The first lower contact 110 may be formed in a first lower contact hole 108a passing through the first insulating interlayer 106 and exposing the upper surface of the first lower conductive pattern 102. The second lower contact 112 may be formed in a second lower contact hole 108b passing through the first insulating interlayer 106 and exposing the upper surface of the second lower conductive pattern 104.

The first lower contact 110 and the first insulating interlayer 106 adjacent thereto may be coplanar with each other. The second lower contact 112 and the first insulating interlayer 106 adjacent thereto may be coplanar with each other.

In example embodiments, the first and second lower contacts 110 and 112 may include a metal. For example, the first and second lower contacts 110 and 112 may include the same metal.

Wiring structures 190 may be arranged on the first insulating interlayer 106 in the first region A1. Each of the wiring structures 190 may have a line shape, and may extend in the first direction X. The wiring structures 190 may be spaced apart from each other in the second direction Y The wiring structures 190 may be arranged in a form in which lines and spaces are repeated.

Each of the wiring structures 190 may have a structure in which a first conductive pattern 122a, a first capping layer pattern 132a, a second capping layer pattern 140a, and a third capping layer pattern 150a are stacked. The second capping layer pattern 140a included in the wiring structures 190 may contact a lower surface of the third capping layer pattern 150a.

A portion of a lower surface of the wiring structures 190 may contact the first lower contact 110. In the cross-sectional view of FIG. 1, the lower surface of one of the wiring structures 190 may contact the first lower contact 110, but at least a portion of the lower surface of each of the wiring structures 190 may contact the first lower contact 110.

The first conductive pattern 122a may include a metal. For example, the first conductive pattern 122a may include tungsten. The first capping layer pattern 132a, the second capping layer pattern 140a and the third capping layer pattern 150a may be formed by different deposition processes. The first capping layer pattern 132a, the second capping layer pattern 140a and the third capping layer pattern 150a may include, e.g., silicon nitride.

In example embodiments, the first capping layer pattern 132a, the second capping layer pattern 140a and the third capping layer pattern 150a may include the same material. Thus, the first capping layer pattern 132a, the second capping layer pattern 140a and the third capping layer pattern 150a may serve as a single capping structure. In some example embodiments, at least one of the first capping layer pattern 132a, the second capping layer pattern 140a, and the third capping layer pattern 150a may include a different material.

In example embodiments, an edge wiring structure 190a may be arranged on an edge of the first region A1 adjacent to an interface between the first region A1 and the second region A2, and the edge wiring structure 190a may have a stacked structure different from a stacked structure of the wiring structure 190. The edge wiring structure 190a may include, e.g., the first conductive pattern 122a, the first capping layer pattern 132a, the second capping layer pattern 140a, a second insulating interlayer 142 and a third capping layer pattern 150a. In the edge wiring structure 190a, the second capping layer pattern 140a may be formed along an upper surface of the first conductive pattern 122a and sidewalls of the first capping layer pattern 132a and the first conductive pattern 122a. The second insulating interlayer 142 may cover a portion of the second capping layer pattern 140a on the sidewall of the first capping pattern 132a and the first conductive pattern 122a. An upper surface of the wiring structure 190 and an upper surface of the edge wiring structure 190a may be substantially coplanar with each other.

A second capping layer 140 and a second insulating interlayer 142 may be stacked on the first insulating interlayer 106 and the second lower contact 112 in the second region A2. The second capping layer 140 may cover at least the first insulating interlayer 106 in the second region A2. Since the second capping layer 140 is formed by the same deposition process as the second capping layer pattern 140a in the first region A1, the second capping layer 140 and the second capping layer pattern 140a in the first and second regions A1 and A2 may include the same material. The second capping layer pattern 140a formed on the surface of the edge wiring structure 190a and the second capping layer 140 on the second region A2 may be connected to each other. The second insulating interlayer 142 may include, e.g., silicon oxide. In example embodiments, upper surfaces of the first insulating interlayer 106 and the second lower contact 112 on the second region A2 may be coplanar with each other. The upper surfaces of the first insulating interlayer 106 and the second lower contact 112 on the second region A2 may be substantially flat. Accordingly, a lower surface of the second capping layer 140 on the second region A2 may contact the upper surfaces of the first insulating interlayer 106 and the second lower contact 112, and the lower surface of the second capping layer 140 on the second region A2 may be coplanar with the upper surfaces of the first insulating interlayer 106 and the second lower contact 112.

The second insulating interlayer 142 may include a protrusion 154 that may relatively protrude, and the protrusion 154 of the second insulating interlayer 142 may be positioned on the second capping layer 140 at an edge of the second region A2 adjacent to the interface between the first region A1 and the second region A2. A third capping layer pattern 150a may be formed on an upper surface of the protrusion 154 of the second insulating interlayer 142. The protrusion 154 of the second insulating interlayer 142 and the third capping layer pattern 150a on the protrusion 154 of the second insulating interlayer 142 are referred to as a protrusion pattern. An upper surface of the protrusion pattern may be substantially coplanar with the upper surface of the wiring structure 190. An uppermost surface of the wiring structure 190 may be substantially coplanar with the upper surface of the third capping layer pattern 150a formed on the upper surface of the protrusion 154 of the second insulating interlayer 142.

On the second region A2, the upper surface of the protrusion 154 of the second insulating interlayer 142 may be higher than an upper surface of the second insulating interlayer 142 other than the protrusion 154. In example embodiments, the upper surface of the second insulating interlayer 142 other than the protrusion 154 may be substantially flat, and may be lower than the upper surface of the first capping layer pattern 132a included in the wiring structure 190.

Uppermost portions of the wiring structure 190, the edge wiring structure 190a, and the protrusion pattern may include the third capping layer patterns 150a. Upper surfaces of the third capping layer patterns 150a included in the wiring structure 190, the edge wiring structure 190a and the protrusion pattern may be substantially coplanar with each other. Lower surfaces of the third capping layer patterns 150a included in the wiring structure 190, the edge wiring structure 190a and the protrusion pattern may be substantially coplanar with each other. The third capping layer pattern 150a included in the wiring structure 190 and the third capping layer pattern 150a on the protrusion 154 of the second insulating interlayer 142 may have flat upper surfaces and flat lower surfaces. Therefore, the third capping layer pattern 150a on the protrusion 154 of the second insulating interlayer 142 may be higher than the upper surface of the first conductive pattern 122a.

The third capping layer pattern 150a on the first region A1 and the third capping layer pattern 150a on the second region A2 may be formed by the same deposition process, and thus the third capping layer pattern 150a on the first region A1 and the third capping layer pattern 150a on the second region A2 may include the same material.

A third insulating interlayer 192 may be disposed on the first insulating interlayer 106 on the first region A1 and the second insulating interlayer 142 on the second region A2. The third insulating interlayer 192 may be disposed on the first insulating interlayer 106 on the first region A1 to fill a space between the wiring structures 190. The third insulating interlayer 192 may cover the second insulating interlayer 142 on the second region A2. The third insulating interlayer 192 may include, e.g., silicon oxide.

In example embodiments, an upper surface of the third insulating interlayer 192 may be substantially coplanar with the upper surfaces of the wiring structures 190, the edge wiring structure 190a, and the protrusion pattern.

A fourth insulating interlayer 194 may cover the upper surfaces of the wiring structures 190, the edge wiring structure 190a, the protrusion pattern, and the third insulating interlayer 192. An upper surface of the fourth insulating interlayer 194 may be higher than the upper surfaces of the wiring structures 190.

An upper contact 202 may pass through the fourth insulating interlayer 194, the third insulating interlayer 192, the second insulating interlayer 142 and the second capping layer 140 on the second region A2, and the upper contact 202 may contact the upper surface of the second lower contact 112. The upper contact 202 may be formed in an upper contact hole 200 passing through the fourth insulating interlayer 194, the third insulating interlayer 192, the second insulating interlayer 142 and the second capping layer 140 on the second region A2.

A lower surface of the upper contact 202 may contact at least a portion of the upper surface of the second lower contact 112. In example embodiments, an entire lower surface of the upper contact 202 may contact the upper surface of the second lower contact 112.

In example embodiments, an uppermost surface of the second lower contact 112 may be substantially coplanar with the lower surface of the second capping layer 140. The uppermost surface of the second lower contact 112 may not be positioned lower than the lower surface of the second capping layer 140. In example embodiments, a bottom surface of the upper contact 202 may be substantially coplanar with the lower surface of the second capping layer 140.

As described above, the wiring structures 190 with repeating lines and spaces may be disposed on the first region A1 of the substrate 100, and the upper contact 202 extending downward from a position higher than the upper surface of the wiring structure 190 and contacting the upper surface of the second lower contact 112 may be disposed on the second region A2 of the substrate 100.

An upper surface of the second lower contact 112 may not be positioned lower than the lower surface of the second capping layer 140. The uppermost surface of the second lower contact 112 may not be lower than an uppermost surface of the first insulating interlayer 106 on the first region A1. The uppermost surface of the second lower contact 112 may be coplanar with or higher than the uppermost surface of the first insulating interlayer 106 on the first region A1.

As the second capping layer 140 and the second insulating interlayer 142 may be disposed on the second lower contact 112, the upper surface of the second lower contact 112 may be protected by the second capping layer 140 and the second insulating interlayer 142. Therefore, the upper surface of the second lower contact 112 may have a target vertical level. Accordingly, the upper contact 202 may have a target vertical height (i.e., vertical length), and a contacting failure between the second lower contact 112 and the upper contact 202 may be decreased.

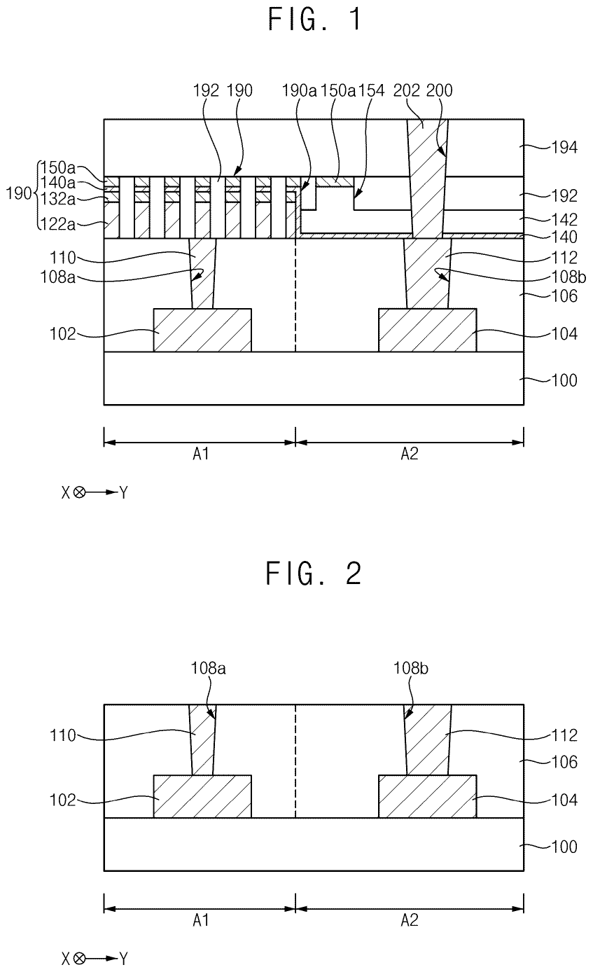

FIGS. 2 to 19 are cross-sectional views illustrating a method for manufacturing a semiconductor device according to example embodiments.

Referring to FIG. 2, a substrate 100 including a first region A1 and a second region A2 may be provided.

A first lower conductive pattern 102 may be formed on the first region A1 of the substrate 100, and a second lower conductive pattern 104 may be formed on the second region A2 of the substrate 100. In example embodiments, a conductive layer may be formed on the first and second regions A1 and A2 of the substrate 100 by a deposition process, and the conductive layer may be patterned to form the first and second lower conductive patterns 102 and 104.

The first and second lower conductive patterns 102 and 104 may include a metal. Since the first and second lower conductive patterns 102 and 104 are formed by the same deposition process, the first and second lower conductive patterns 102 and 104 may include the same material.

A first insulating interlayer 106 may be formed on the substrate 100 to cover the first and second lower conductive patterns 102 and 104. The first insulating interlayer 106 may include, e.g., silicon oxide. The first insulating interlayer 106 may be formed, e.g., by atomic layer deposition process or chemical vapor deposition process.

A portion of the first insulating interlayer 106 on the first region A1 of the substrate 100 may be etched to form a first lower contact hole 108a. A portion of the first insulating interlayer 106 on the second region A2 of the substrate 100 may be etched to form a second lower contact hole 108b. An upper surface of the first lower conductive pattern 102 may be exposed by a bottom of the first lower contact hole 108a. An upper surface of the second lower conductive pattern 104 may be exposed by a bottom of the second lower contact hole 108b.

In example embodiments, a diameter of the first lower contact hole 108a and a diameter of the second lower contact hole 108b may be different from each other. For example, the diameter of the second lower contact hole 108b may be greater than the diameter of the first lower contact hole 108a. However, the diameters of the first and second lower contact holes 108a and 108b are not limited thereto. For example, the diameters of the first and second lower contact holes 108a and 108b may be the same.

A first conductive layer may be formed on the first insulating interlayer 106 to fill the first and second lower contact holes 108a and 108b. The first conductive layer may be planarized until an upper surface of the first insulating interlayer 106 is exposed. Therefore, a first lower contact 110 may be formed in the first lower contact hole 108a, and a second lower contact 112 may be formed in the second lower contact hole 108b.

Upper surfaces of the first insulating interlayer 106, the first lower contact 110, and the second lower contact 112 may be exposed, and the upper surfaces of the first insulating interlayer 106, the first lower contact 110, and the second lower contact 112 may be coplanar with each other.

In example embodiments, the first conductive layer may include a metal. Therefore, the first and second lower contacts 110 and 112 may include the metal.

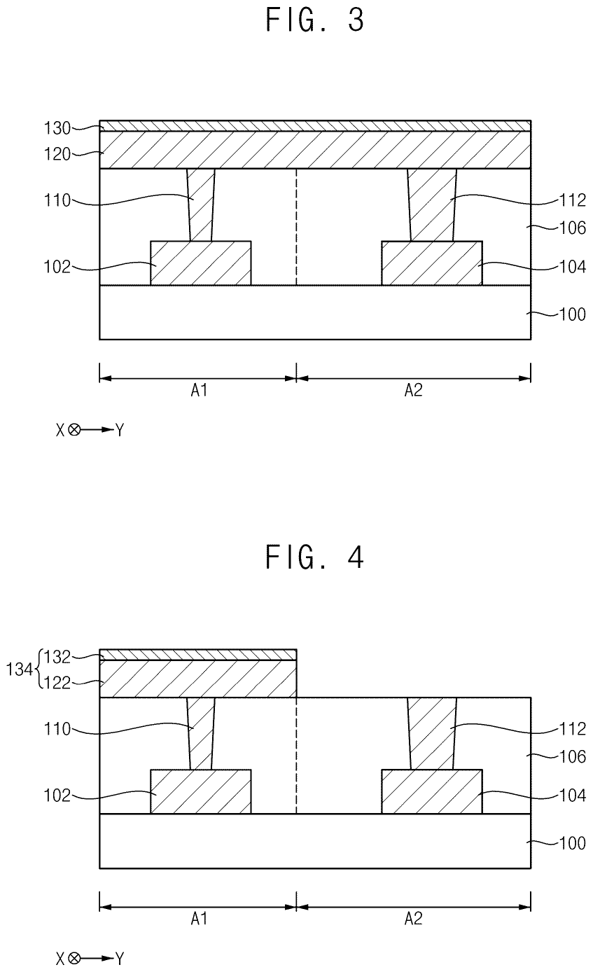

Referring to FIG. 3, a second conductive layer 120 may be formed on the upper surfaces of the first insulating interlayer 106, the first lower contact 110, and the second lower contact 112. A first capping layer 130 may be formed on the second conductive layer 120 to cover the second conductive layer 120.

In example embodiments, the second conductive layer 120 may include a metal that can be etched through a patterning process. The second conductive layer 120 may include, e.g., tungsten.

The first capping layer 130 may include an insulation material having an etching selectivity with respect to the second conductive layer 120. The first capping layer 130 may include, e.g., silicon nitride.

The first capping layer 130 may serve as a portion of a capping structure for capping of the second conductive layer 120. Therefore, the first capping layer 130 may be formed to have a first thickness less than a target thickness of the capping structure. For example, the first thickness may be about 40% to about 60% of the target thickness of the capping structure.

Referring to FIG. 4, the first capping layer 130 and the second conductive layer 120 on the second region A2 may be sequentially etched to form a first structure 134 in which a preliminary second conductive layer pattern 122 and a preliminary first capping layer pattern 132 are stacked on the first insulating interlayer 106 and the first lower contact 110 on the first region A1.

The first structure 134 may cover the upper surface of the first insulating interlayer 106 and the first lower contact 110 on the first region A1. The first structure 134 may not be formed on the upper surface of the first insulating interlayer 106 and the second lower contact 112 on the second region A2. Therefore, the upper surface of the first insulating interlayer 106 and the second lower contact 112 on the second region A2 of the substrate 100 may be exposed.

Since the first conductive patterns may not be formed on the second region A2, the first capping layer 130 and the second conductive layer 120 on the second region A2 may be removed.

When the process is performed, sidewalls of the preliminary second conductive layer pattern 122 and the preliminary first capping layer pattern 132 may be exposed at an interface between the first and second regions A1 and A2.

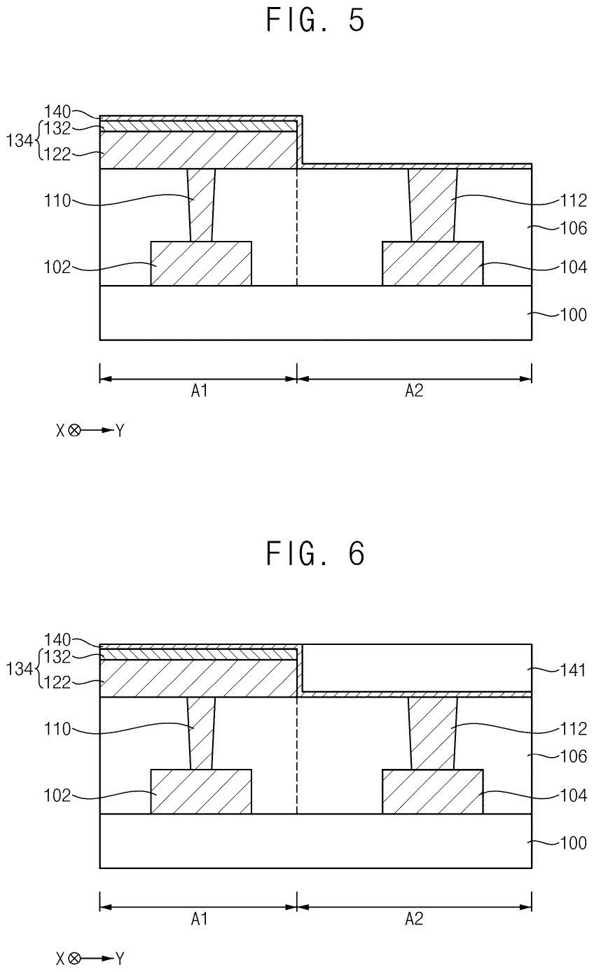

Referring to FIG. 5, a second capping layer 140 may be conformally formed on an upper surface and sidewalls of the first structure 134, the upper surface of the first insulating interlayer 106, and the upper surface of the second lower contact 112. The second capping layer 140 may be formed along the upper surface and sidewalls of the preliminary first capping layer pattern 132, the sidewalls of the preliminary second conductive layer pattern 122, the upper surface of the first insulating interlayer 106, and the upper surface of the second lower contact 112. The second capping layer 140 may include, e.g., silicon nitride.

In example embodiments, the second capping layer 140 may be formed to have a thickness less than a thickness of the preliminary first capping layer pattern 132. In example embodiments, the second capping layer 140 may be formed by an atomic layer deposition process.

The sidewalls of the second lower contact 112 and the preliminary second conductive layer pattern 122 may have a bad adhesion property with the preliminary second insulating interlayer 141(refer to FIG. 6) subsequently formed. Therefore, the second capping layer 140 may be interposed between the preliminary second insulating interlayer 141 and the preliminary second conductive layer pattern 122 and between the preliminary second insulating interlayer 141 and the second lower contact 112, and the second capping layer 140 may serve as an adhesive layer that improves adhesion properties with the preliminary second insulating interlayer 141. The second capping layer 140 may cover the sidewall of the preliminary second conductive layer pattern 122 and the upper surface of the second lower contact 112.

Referring to FIG. 6, a preliminary second insulating interlayer 141 may be formed on the second capping layer 140. The preliminary second insulating interlayer 141 may include, e.g., silicon oxide. The preliminary second insulating interlayer 141 may be formed, e.g., by an atomic layer deposition process or a chemical vapor deposition process.

Thereafter, the preliminary second insulating interlayer 141 may be planarized until an upper surface of the second capping layer 140 on the first region A1 is exposed. The preliminary second insulating interlayer 141 may be formed only on the upper surface of the second capping layer 140 on the second region A2.

The upper surface of the second capping layer 140 on the first region A1 and an upper surface of the preliminary second insulating interlayer 141 may be substantially coplanar with each other.

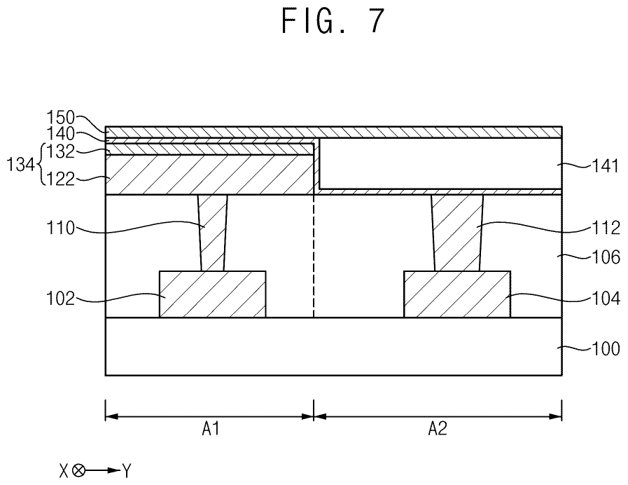

Referring to FIG. 7, a third capping layer 150 may be formed on the upper surfaces of the second capping layer 140 and the preliminary second insulating interlayer 141. The third capping layer 150 may include, e.g., silicon nitride.

When the processes are performed, the preliminary first capping layer pattern 132, the second capping layer 140, and the third capping layer 150 may be stacked on the preliminary second conductive pattern 122 on the first region A1. The third capping layer 150 may be formed such that a thickness of a structure in which the preliminary first capping layer pattern 132, the second capping layer 140, and the third capping layer 150 are stacked is the same as the target thickness of the capping layer structure subsequently formed.

The second capping layer 140, the preliminary second insulating interlayer 141 and the third capping layer 150 may be stacked on the first insulating interlayer 106 and the second lower contact 112 on the second region A2 of the substrate 100.

The preliminary first capping layer pattern 132 may be formed only on the preliminary second conductive pattern 122 on the first region A1. The second capping layer 140 may be formed continuously on the upper surface and sidewall of the first structure 134 on the first region A1 and the first insulating interlayer 106 and the second lower contact 112 on the second region A2. The third capping layer 150 may be formed continuously on the second capping layer 140 on the first region A1 and the preliminary second insulating interlayer 141 on the second region A2.

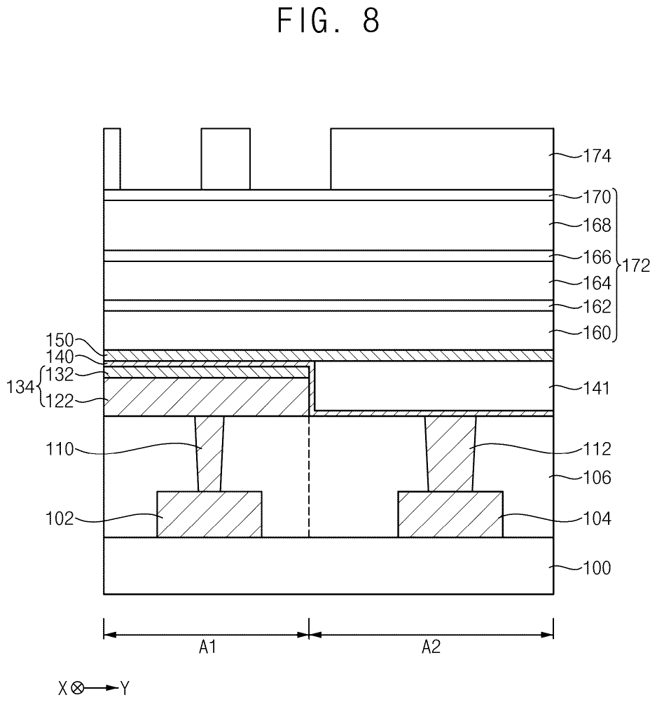

Referring to FIG. 8, a mask layer structure 172 may be formed on the third capping layer 150. The mask layer structure 172 may include stacked layers for forming an etching mask.

In example embodiments, the mask layer structure 172 may include a first mask layer 160, a first separation layer 162, a second mask layer 164, a second separation layer 166, a third mask layer 168 and a third separation layer 170 stacked. Therefore, the first mask layer 160, the first separation layer 162, the second mask layer 164, the second separation layer 166, the third mask layer 168 and the third separation layer 170 may be sequentially formed on the third capping layer 150.

The first mask layer 160 may be formed using a material having a high etching selectivity with respect to the third capping layer 150. For example, when the third capping layer 150 is formed of silicon nitride, the first mask layer 160 may be formed of silicon oxide or a polysilicon layer.

Thereafter, the first photoresist pattern 174 may be formed on a third separation layer 170 corresponding to an uppermost of the mask layer structure 172.

The first photoresist pattern 174 may cover most of an upper portion of the second region A2, excluding an edge portion of the second region A2 adjacent to the first region A1. The first photoresist pattern 174 on the first region A1 may have a plurality of line patterns spaced apart from each other. For example, in the first photoresist pattern 174 on the first region A1, a width of the line pattern and a space between the line patterns may have a ratio of about 3:5.

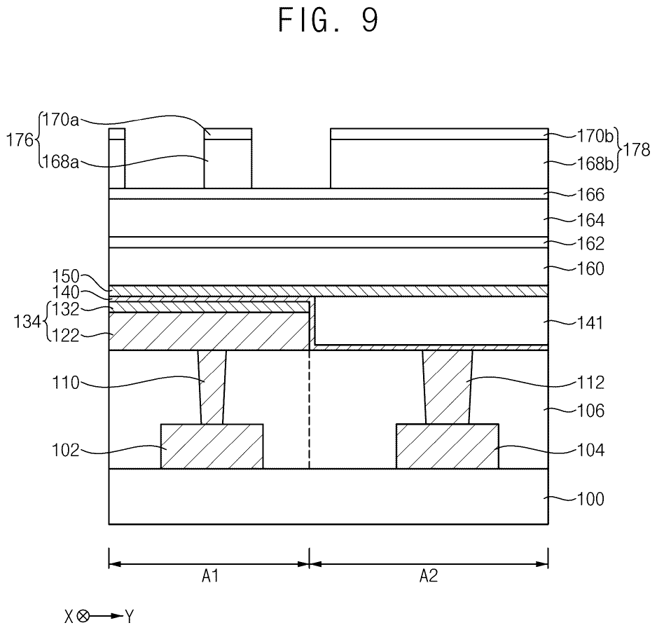

Referring to FIG. 9, the third separation layer 170 and the third mask layer 168 corresponding to an upper portion of the mask layer structure 172 may be patterned using the first photoresist pattern 174 as an etching mask. Accordingly, second structures 176 in which a first mask pattern 168a and a first separation layer pattern 170a are stacked may be formed on the first region A1, and third structures 178 in which a second mask pattern 168b and a second separation layer pattern 170b are stacked may be formed on the second region A2.

The second structures 176 may extend in the first direction X, and may have a plurality of line patterns spaced apart from each other. The third structure 178 may cover most of an upper portion of the second region A2, excluding the edge portion of the second region A2 adjacent to the first region A1.

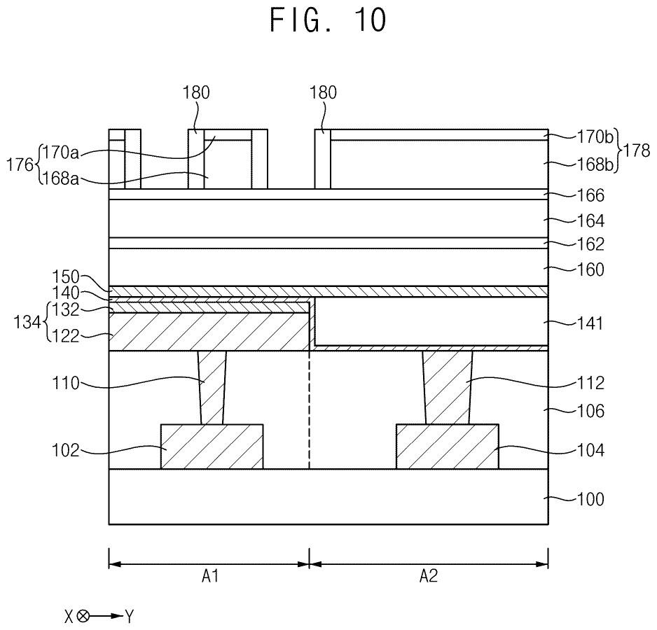

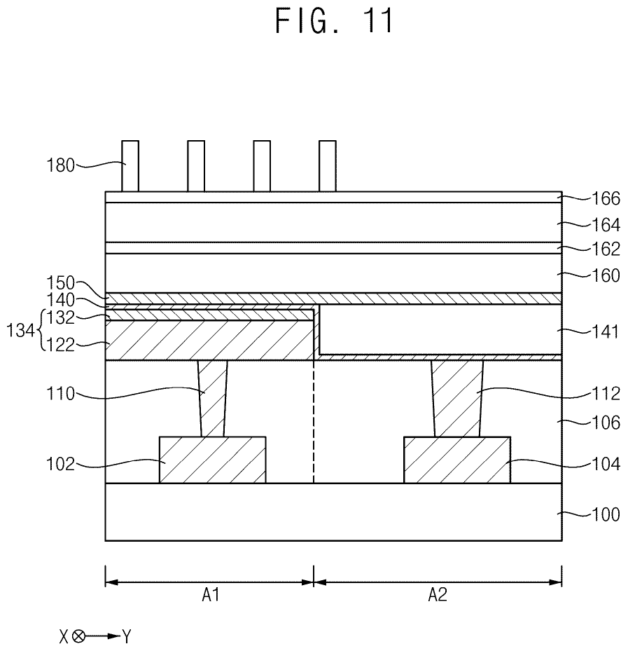

Referring to FIG. 10, first spacers 180 may be formed on sidewalls of the second structures 176 and the third structure 178. The first spacers 180 may serve as a first mandrel pattern in a patterning process. The first spacers 180 may be formed on the first region A1 and the edge portions of the second region A2 adjacent to the first region A1. The first spacers 180 may extend in the first direction X.

Referring to FIG. 11, the second and third structures 176 and 178 may be removed. Accordingly, only the first spacers 180 may remain on the second separation layer 166. For example, on the first region A1, a width of the first spacer 180 and a space between the first spacers 180 may have a ratio of about 1:3.

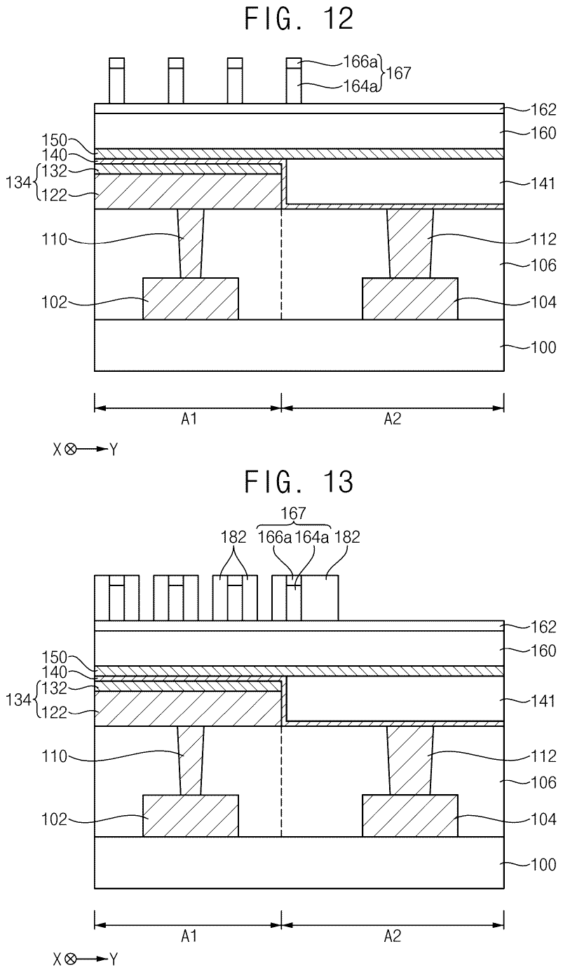

Referring to FIG. 12, the second separation layer 166 and the second mask layer 164 may be patterned using the first spacers 180 as an etching mask to form fourth structures 167 in which a third mask pattern 164a and a third separation layer pattern 166a are stacked on the first region A1. At this time, the second separation layer 166 and the second mask layer 164 on the second region A2 may be mostly removed, and a fourth structure 167 may be formed only on the edge of the second region A2 adjacent to the first region A1.

The fourth structures 167 may extend in the first direction X, and may have a plurality of line patterns spaced apart from each other.

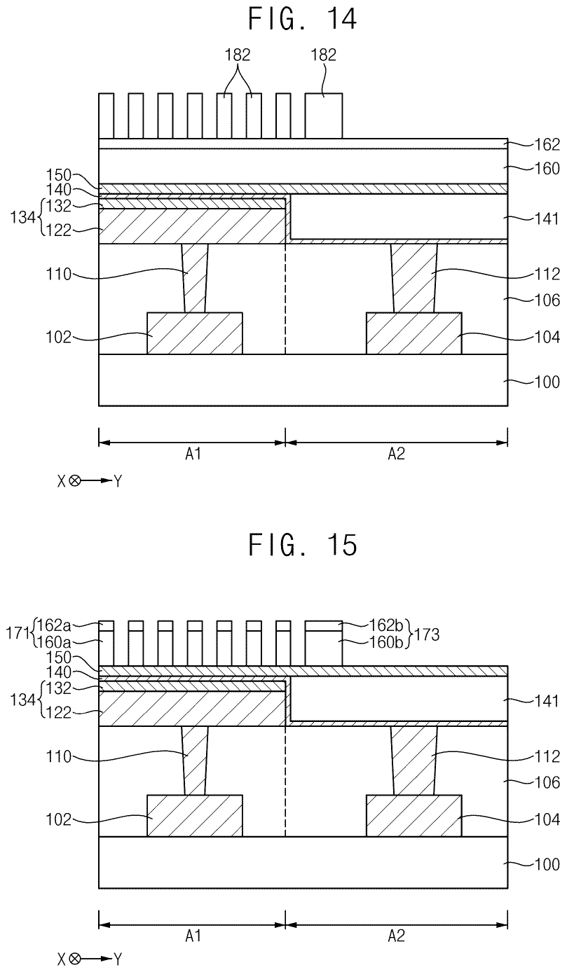

Referring to FIG. 13, second spacers 182 may be formed on sidewalls of the fourth structures 167. The second spacers 182 may be formed on the first region A1. The second spacers 182 may extend in the first direction X.

The second spacers 182 may be formed by performing an anisotropic etching process of a second spacer layer after forming the second spacer layer. In the etching process, an etching loading of the second spacer layer formed on the first region A1 and an etching loading of the second spacer layer formed on the second region A2 may be different from each other. Accordingly, a width of the second spacer 182 formed on the first region A1 and a width of the second spacer 182 formed on the second region A2 may be different from each other. In example embodiments, the width of the second spacer 182 formed on the second region A2 may be greater than the width of the second spacer 182 formed on the first region A1.

Referring to FIG. 14, the fourth structures 167 may be removed. Accordingly, only the second spacers 182 may remain on the first separation layer 162.

The second spacers 182 may be arranged on the first region A1. One of the second spacers 182 may also be disposed on the edge portion of the second region A2 adjacent to the first region A1. For example, on the first region A1, the width of the second spacer 182 and a space between the second spacers 182 may have a ratio of about 1:1.

Referring to FIG. 15, the first separation layer 162 and the first mask layer 160 may be patterned using the second spacers 182 as an etching mask to form fifth structures 171 in which the fourth mask pattern 160a and the fourth separation layer pattern 162a are stacked on the first region A1. The fifth structures 171 may be used as an etching mask for patterning the first to third capping layers 132, 140 and 150 and the preliminary second conductive pattern 122 under the fifth structure 171.

In this case, most of the first separation layer 162 and the first mask layer 160 on the second region A2 may be removed, and a sixth structure 173 in which the fifth mask pattern 160b and the fifth separation layer pattern 162b are stacked may be formed only on the edge portion of the second region A2 adjacent to the first region A1.

In example embodiments, a width of the sixth structure 173 formed on the second region A2 may be greater than the width of each of the fifth structures 171 formed on the first region A1. In the etching process of the first separation layer 162 and the first mask layer 160 for forming the fifth structures 171, the third capping layer 150 corresponding an uppermost capping layer may be used as an etch stop layer. That is, the first separation layer 162 and the first mask layer 160 on the first region A1 and the second region A2 may be etched using the second spacers 182 as an etch mask so as to expose the third capping layer 150.

Unlike the present embodiment, if the third capping layer is not formed, the etching process for forming the fifth structures may over-etch not only the first separation layer and the first mask layer on the second region, but also the preliminary second insulating interlayer therebelow. Accordingly, after forming the fifth structure, a thickness of the preliminary second insulating interlayer on the second region may be significantly decreased.

However, in example embodiments, since the third capping layer 150 is formed on the preliminary second insulating interlayer 141 on the second region A2, the etching process for forming the fifth structure 171 may be stopped when the third capping layer 150 is exposed. Therefore, the third capping layer 150 may not be etched, and only the first separation layer 162 and the first mask layer 160 on the second region A2 may be etched. In the etching process, the preliminary second insulating interlayer 141 disposed under the third capping layer 150 on the second region A2 may not be etched. Accordingly, after forming the fifth structure 171, the thickness of the preliminary second insulating interlayer 141 may not be decreased.

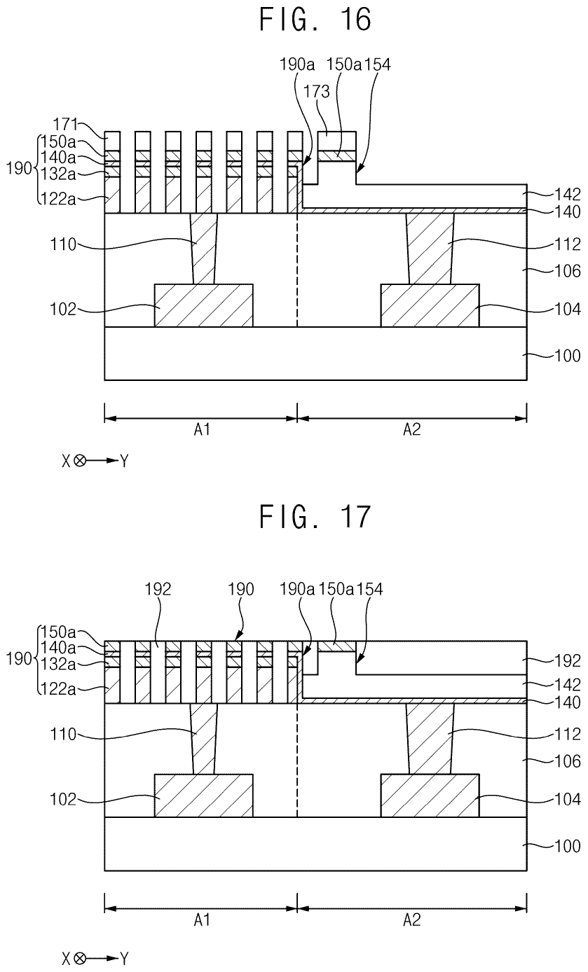

Referring to FIG. 16, the third capping layer 150, the second capping layer 140, the preliminary first capping layer pattern 132 and the preliminary second conductive pattern 122 on the first region A1 are sequentially etched using the fifth structure 171 as an etching mask to form wiring structures 190 in which a first conductive pattern 122a, a first capping layer pattern 132a, a second capping layer pattern 140a and a third capping layer pattern 150a are stacked on the first region A1. The wiring structures 190 may extend in the first direction X, and may be arranged to be spaced apart from each other in the second direction Y

In example embodiments, an edge wiring structure 190a in which the first conductive pattern 122a, the first capping layer pattern 132a, the second capping layer 140, and the third capping layer pattern 150a are stacked may be formed on an edge portion of the first region A1 adjacent to an interface between the first region A1 and the second region A2. In the edge wiring structure 190a, the second capping layer 140 may cover an upper surface of the first capping layer pattern 132a and sidewalls of the first capping layer pattern 132a and the first conductive pattern 122a. In the second region A2, the second insulating interlayer 142 may cover the surface of the second capping layer 140.

Since most of the second region A2 is exposed by the fifth structure 171 and sixth structure 173 in the etching process, the third capping layer 150 on the second region A2 may be removed, and the preliminary second insulating interlayer 141 under the third capping layer 150 may be partially removed depending on an etching selectivity. Therefore, a second insulating interlayer 142 having a thinner thickness than the preliminary second insulating interlayer 141 may be formed.

In the etching process, the third capping layer 150 and the preliminary second insulating interlayer 141 under the sixth structure 173 may not be removed. Accordingly, the second insulating interlayer 142 under the sixth structure 173 may relatively protrude, and thus the second insulating interlayer 142 under the sixth structure 173 may serve as a protrusion 154 of the second insulating interlayer 142. Additionally, the third capping layer pattern 150a may be formed on the upper surface of the protrusion 154 of the second insulating interlayer 142. The protrusion 154 of the second insulating interlayer 142 and the third capping layer pattern 150a thereon may be referred to as a protrusion pattern.

After performing the etching process, the second capping layer 140 and the second insulating interlayer 142 may remain on the first insulating interlayer 106 and the second lower contact 112 on the second region A2. The second capping layer 140 on the second region A2 may cover at least an entire upper surface of the first insulating interlayer 106 on the second region A2.

Unlike the present embodiment, when the third capping layer is not formed, most of the preliminary second insulating interlayer may be removed on the second capping layer on the second region during the process described with reference to FIG. 15. Therefore, a thickness of the preliminary second insulating interlayer may be decreased. In this case, when the etching process for forming the wiring structure is performed, the preliminary second insulating interlayer may be completely removed, and an upper portion of the second lower contact disposed thereunder may also be removed. A vertical level of the upper surface of the second lower contact may be reduced.

However, in example embodiments, since the preliminary second insulating interlayer 141 was not removed and remained with a sufficient thickness on the second capping layer 140 on the second region A2 during the process described with reference to FIG. 15, the preliminary second insulating interlayer may remain with at least a portion of the thickness, in the etching process for forming the wiring structure. Therefore, the second insulating interlayer 142 may be formed. Since the second insulating interlayer 142 is formed on the second capping layer 140 on the second region A2, the second capping layer 140 may not be exposed. Accordingly, after performing the etching process, a vertical level of the upper surface of the second lower contact 112 may not be decreased.

Referring to FIG. 17, a preliminary third insulating interlayer may be formed on the wiring structures 190, the edge wiring structure 190a, the protrusion pattern and the second insulating interlayer 142. The preliminary third insulating interlayer may be formed to fill a space between the wiring structures 190 and to sufficiently cover the wiring structures 190. An entire upper surface of the preliminary third insulating interlayer may be formed higher than an upper surfaces of the wiring structures 190.

The preliminary third insulating interlayer may include, e.g., silicon oxide. The preliminary third insulating interlayer may be formed by, e.g., an atomic layer deposition process or a chemical vapor deposition process.

Thereafter, the preliminary third insulating interlayer may be planarized until the third capping layer patterns 150a are exposed to form a third insulating interlayer 192. When the planarization process is performed, the fifth structure 171 and the sixth structure 173 may also be removed.

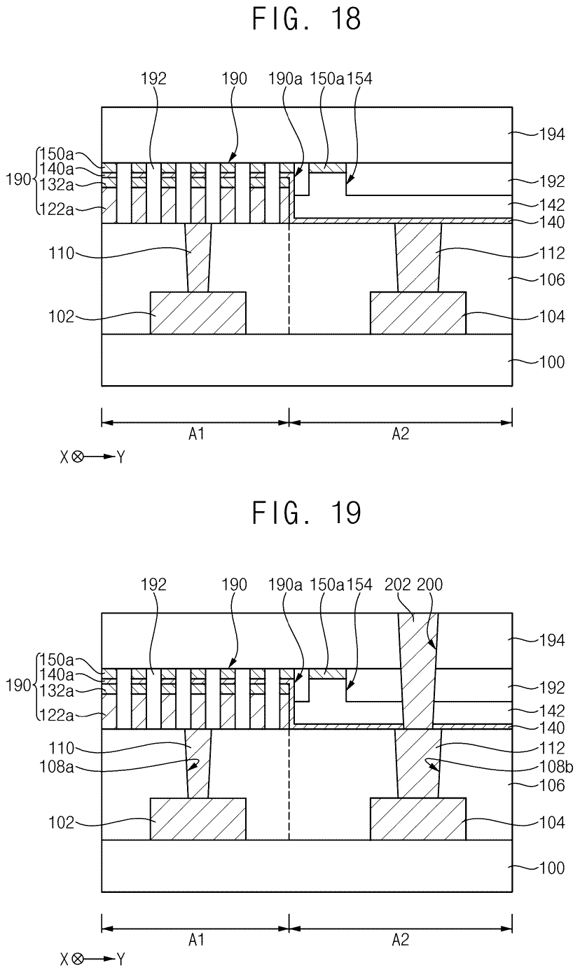

Referring to FIG. 18, a fourth insulating interlayer 194 may be formed on the third insulating interlayer 192 and the third capping layer pattern 150a. An upper surface of the fourth insulating interlayer 194 may be higher than the upper surfaces of the wiring structures 190.

Referring to FIG. 19, portions of the fourth insulating interlayer 194, the third insulating interlayer 192, the second insulating interlayer 142, and the second capping layer 140 on the second region A2 may be etched to form an upper contact hole 200 exposing at least a portion of the upper surface of the second lower contact 112.

A third conductive layer may be formed on the fourth insulating interlayer 194 to fill the upper contact hole 200, and a planarization process may be performed until the upper surface of the fourth insulating interlayer 194 is exposed to form an upper contact 202 filling the upper contact hole 200. A bottom surface of the upper contact 202 may be positioned on a top surface of the second lower contact 112.

The bottom surface of the upper contact 202 may contact at least a portion of the top surface of the second lower contact 112. In example embodiments, an entire bottom surface of the upper contact 202 may contact the top surface of the second lower contact 112.

An uppermost surface of the second lower contact 112 may be substantially coplanar with a bottom surface of the second capping layer 140. That is, the uppermost surface of the second lower contact 112 may not be positioned lower than the bottom surface of the second capping layer 140. In example embodiments, the bottom surface of the upper contact 202 may be substantially coplanar with the bottom surface of the second capping layer 140. In addition, the uppermost surface of the second lower contact 112 may not be positioned lower than the uppermost surface of the first insulating interlayer 106 on the first region A1.

Unlike the present embodiment, if the second lower contact is partially removed in the processes before forming the upper contact, a vertical level of the upper surface of the second lower contact may be lower than the bottom surface of the second capping layer. In this case, since a vertical height of the upper contact increases, forming of an upper contact hole for forming the upper contact may be difficult. Therefore, the upper contact hole may not expose an upper surface of the second lower contact.

However, in example embodiments, the second lower contact 112 is not removed by the processes before forming the upper contact 202. The second lower contact 112 may be substantially coplanar with the upper surface of the adjacent first insulating interlayer 106. Since the upper surface of the second lower contact 112 has a sufficiently high vertical level, the vertical height of the upper contact 202 may be decreased. Thus, defects in which the upper contact 202 and the second lower contact 112 do not make contact may be decreased.

By performing the above processes, wiring structures 190 with repeating lines and spaces may be formed on the first region A1 of the substrate 100, and the upper contact 202 extending downward from a surface higher than the upper surface of the wiring structure 190 and contacting the upper surface of the second lower contact 112 may be formed on the second region A2 of the substrate 100.

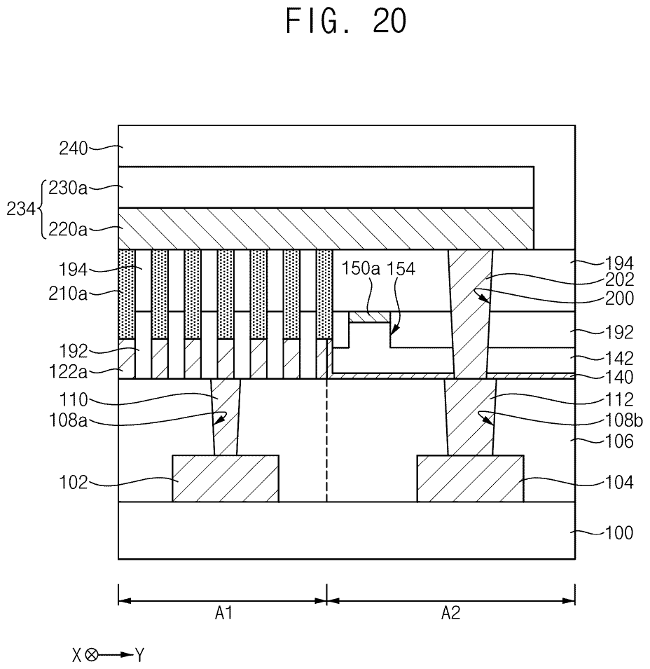

FIGS. 20 to 22 are cross-sectional views and plan views illustrating semiconductor devices according to example embodiments.

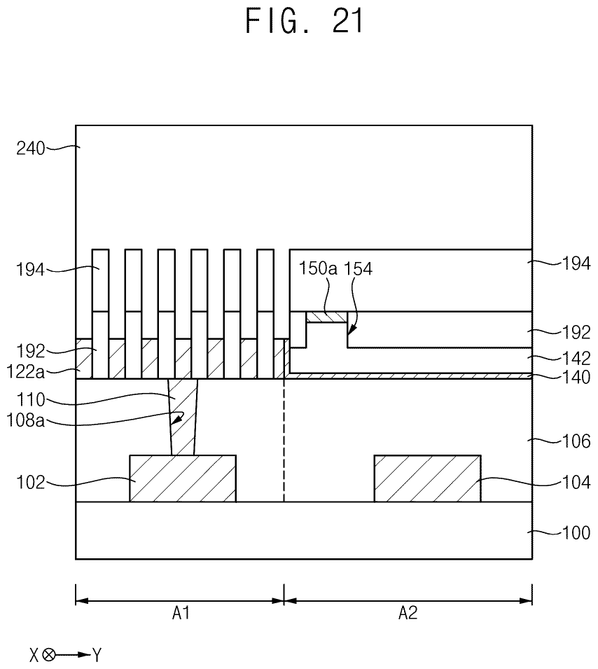

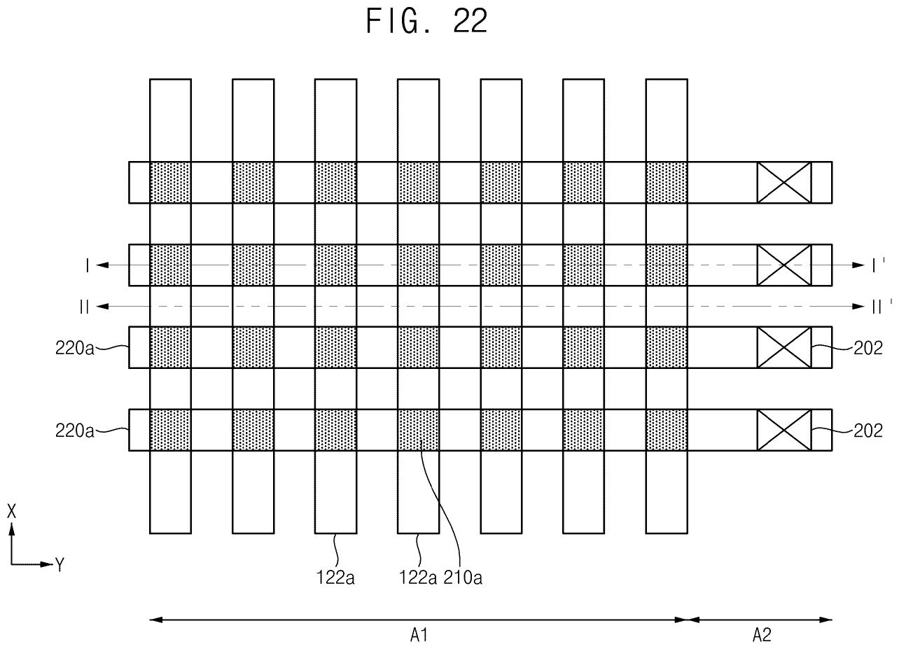

FIG. 20 is a cross-sectional view taken along line I-I′ of FIG. 22, and FIG. 21 is a cross-sectional view taken along line II-II′ of FIG. 22.

Referring to FIGS. 20 to 22, a substrate 100 including a first region A1 and a second region A2 may be provided. A first lower conductive pattern 102 may be disposed on the first region A1 of the substrate 100. Second lower conductive patterns 104 may be disposed on the second region A2 of the substrate 100. A first insulating interlayer 106 covering the first and second lower conductive patterns 102 and 104 may be disposed on the substrate 100.

A first lower contact 110 may contact an upper surface of the first lower conductive pattern 102 passing through the first insulating interlayer 106 from an upper surface of the first insulating interlayer 106. A second lower contact 112 may contact an upper surface of the second lower conductive pattern 104 passing through the first insulating interlayer 106 from the upper surface of the first insulating interlayer 106.

The first lower conductive pattern 102, the second lower conductive pattern 104, the first insulating interlayer 106, the first lower contact 110 and the second lower contact 112 may be the same as the first lower conductive pattern 102, the second lower conductive pattern 104, the first insulating interlayer 106, the first lower contact 110 and the second lower contact 112 described with reference to FIG. 1, respectively.

A first conductive pattern 122a may be disposed on the first insulating interlayer 106 on the first region A1. The first conductive pattern 122a may have a line shape, and may extend in the first direction X. In addition, the first conductive patterns 122a may be spaced apart from each other in a second direction Y perpendicular to the first direction X. The first conductive pattern 122a may be arranged so that lines and spaces are repeated.

A plurality of memory patterns 210a may be disposed on the first conductive pattern 122a on the first region A1. The plurality of memory patterns 210a may be regularly spaced apart from each other in the first direction X on a single first conductive pattern 122a having the line shape.

Each of the memory patterns 210a may have an island shape. Bottom surfaces of the memory patterns 210a may contact a top surface of the first conductive pattern 122a.

The memory pattern 210a may have a high resistance state or a low resistance state depending on a direction of an applied voltage and magnitude of the applied voltage, and thus data may be stored in the memory pattern 210a.

In example embodiments, the memory pattern 210a may include an ovonic threshold switch (OTS) material. The OTS material may include a chalcogen material such as S, Se, and Te.

The OTS material may be the chalcogenide material mixed with materials such as Zn, As, Si, and Ge.

In example embodiments, the OTS material may include GeSe, GeS, AsSe, AsTe, AsS SiTe, SiSe, SiS, GeAs, SiAs, SnSe, SnTe, GeAsTe, GeAsSe, AlAsTe, AlAsSe, SiAsSe, SiAsTe, GeSeTe, GeSeSb, GaAsSe, GaAsTe, InAsSe, InAsTe, SnAsSe, SnAsTe, GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, GeAsTeZn, etc. However, the OTS material may not be limited to the above material. For example, the OTS material may include a material further doped with B, C, N, and/or O in the above material. Furthermore, the OTS material may include a five-component material or a six-component material manufactured by combining elements included in the above materials.

A second capping layer 140 and a second insulating interlayer 142 may be stacked on the first insulating interlayer 106 and the second lower contact 112 on the second region A2. An entire upper surface of the first insulating interlayer 106 on the second region A2 may be covered by the second capping layer 140.

In example embodiments, a bottom surface of the second capping layer 140 may be substantially coplanar with a bottom surface of the first conductive pattern 122a.

A second insulating interlayer 142 may include a protrusion 154 that may relatively protrude, and the protrusion 154 of the second insulating interlayer 142 may be positioned on the second capping layer 140 at an edge of the second region A2 adjacent to an interface between first region A and the second region B. A third capping layer pattern 150a may be formed on an upper surface of the protrusion 154 of the second insulating interlayer 142. Accordingly, a protrusion pattern including the protrusion 154 of the second insulating interlayer 142 and the third capping layer pattern 150a may be disposed on the second capping layer 140 at the edge of the second region A2 adjacent to the interface between the first region A1 and the second region A2. The upper surface of the protrusion 154 of the second insulating interlayer 142 may protrude further than the upper surface of the second insulating interlayer 142 excluding the protrusion 154.

In example embodiments, the second capping layer 140 and the third capping layer pattern 150a may include silicon nitride.

A third insulating interlayer 192 may be disposed on the first insulating interlayer 106 of the first region A1 and the second insulating interlayer 142 of the second region A2. The third insulating interlayer 192 may fill a space between the first conductive patterns 122a and a space between the memory patterns 210a, and may cover the second insulating interlayer 142.

In example embodiments, upper surfaces of the third insulating interlayer 192 on the first and second regions A1 and A2 may be coplanar with each other. In example embodiments, the upper surface of the third insulating interlayer 192 may be substantially coplanar with an upper surface of the third capping layer pattern 150a.

A fourth insulating interlayer 194 may be disposed on the third insulating interlayer 192 and the third capping layer pattern 150a in the first region A1 and the second region A2. The fourth insulating interlayer 194 may fill a gap between the memory patterns 210 in the second direction. In example embodiments, an upper surface of the fourth insulating interlayer 194 may be substantially coplanar with an upper surfaces of the memory patterns 210a.

On the second region A2, an upper contact 202 may contact an upper surface of the second lower contact 112 passing through the fourth insulating interlayer 194, the third insulating interlayer 192, the second insulating interlayer 142 and the second capping layer 140.

A lower surface of the upper contact 202 may contact at least a portion of the upper surface of the second lower contact 112. In example embodiments, an entire lower surface of the upper contact 202 may contact the upper surface of the second lower contact 112.

In example embodiments, a top surface of the second lower contact 112 may be substantially coplanar with a bottom surface of the second capping layer 140. That is, the top surface of the second lower contact 112 may not be positioned lower than the bottom surface of the second capping layer 140. The bottom surface of the upper contact 202 may be substantially coplanar with the bottom surface of the second capping layer 140. In addition, the top surface of the second lower contact 112 may not be positioned lower than a top surface of the first insulating interlayer 106 on the first region A1. That is, the top surface of the second lower contact 112 may be coplanar with or higher than the top surface of the first insulating interlayer 106 on the first region A1.

An upper wiring structure 234 in which a second conductive pattern 220a and a fourth capping layer pattern 230a are stacked may be disposed on the fourth insulating interlayer 194, the memory pattern 210a and the upper contact 202. The upper wiring structure 234 may have a line shape extending from the first region A1 to the second region A2 in the second direction Y A plurality of upper wiring structures 234 may be disposed to be spaced apart from each other in the first direction X. In example embodiments, the second conductive pattern 220a may serve as a bit line.

A bottom surface of the second conductive pattern 220a may contact the memory pattern 210a. The second conductive pattern 220a may extend from the first region A1 to the second region A2, and a lower surface of the second conductive pattern 220a may contact an upper surface of the upper contact 202. Therefore, the upper contact 202 may be electrically connected to the second conductive pattern 220a.

In example embodiments, the third capping layer pattern 150a on the protrusion 154 of the second insulating interlayer 142 may be positioned higher than an upper surface of the first conductive pattern 122a, and may be positioned lower than the lower surface of the second conductive pattern 220a.

A fifth insulating interlayer 240 may be disposed on the fourth insulating interlayer 194 to cover the upper wiring structure 234. The fifth insulating interlayer 240 may fill a gap between the memory patterns 210a in the first direction.

The semiconductor device may include memory cells including the first conductive pattern 122a, the memory pattern 210a, and the second conductive pattern 220a formed on the first region A1 of the substrate 100. An upper contact 202 may be formed on the second region A2 of the substrate 100. The upper contact 202 may extend downward, and may contact the upper surface of the second lower contact 112.

The upper surface of the second lower contact 112 may not be positioned lower than the bottom surface of the second capping layer 140 on the second region A2. Additionally, the upper surface of the second lower contact 112 may not be positioned lower than an uppermost surface of the first insulating interlayer 106 on the first region A1. Therefore, the upper contact 202 may have a target vertical height, and a contacting failure between the second lower contact 112 and the upper contact 202 may be decreased.

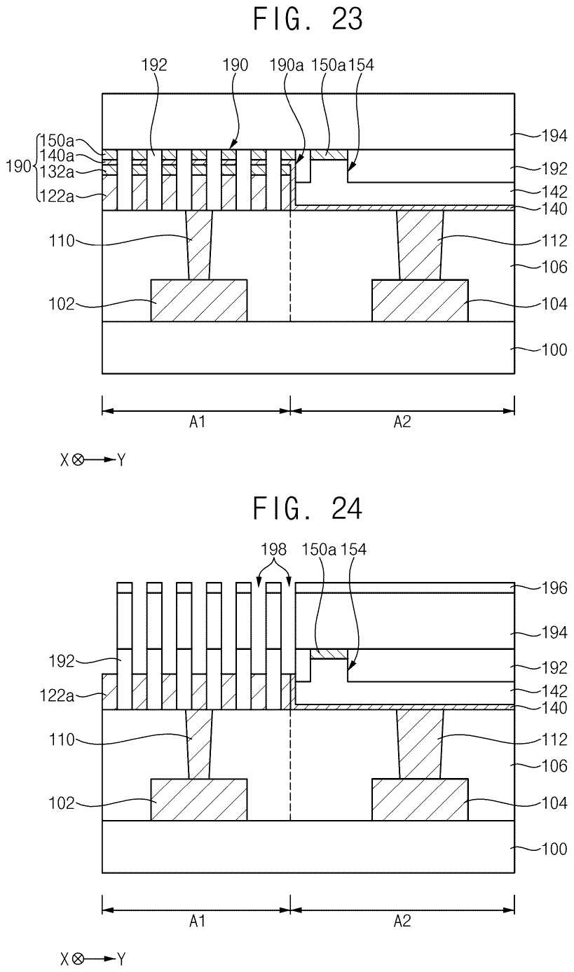

FIGS. 23 to 32 are cross-sectional views illustrating a method of manufacturing a semiconductor device according to example embodiments.

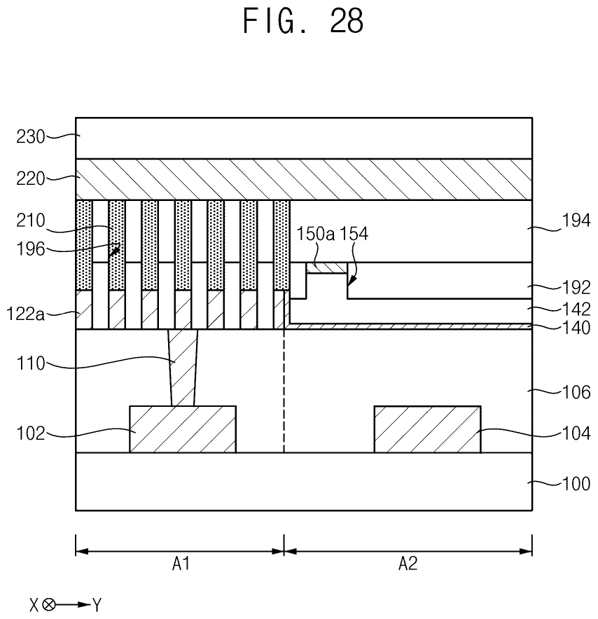

FIGS. 23 to 27, 29, and 31 are cross-sectional views taken along line I-I′ of FIG. 22. FIGS. 28, 30, and 32 are cross-sectional views taken along line II-II′ of FIG. 22.

Referring to FIG. 23, the processes described with reference to FIGS. 2 to 18 may be performed to form the structure illustrated in FIG. 18.

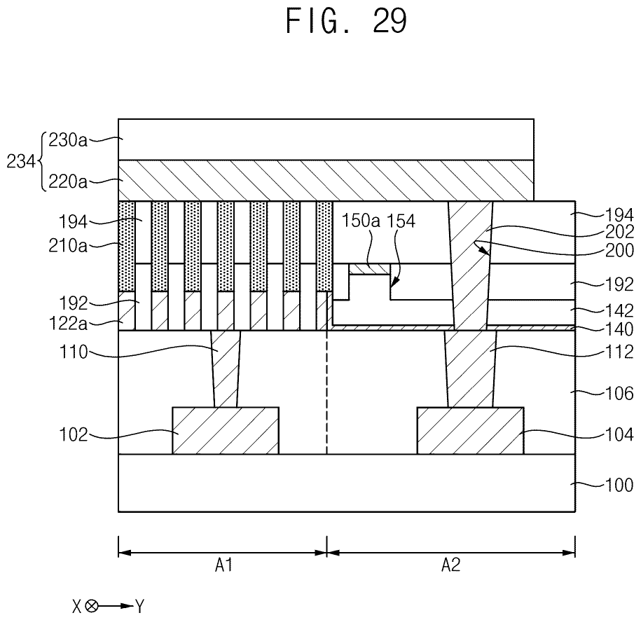

Referring to FIG. 24, a first etching mask pattern 196 may be formed on the fourth insulating interlayer 194. The first etching mask pattern 196 may be positioned on the first region A1 to selectively expose a portion overlapping with the wiring structure 190 (referred to FIG. 29). That is, the first etching mask pattern 196 may cover a portion between the wiring structures 190 on the first region A1, and may have a line shape extending in the first direction X. In addition, the first etching mask pattern 196 may cover an entire upper surface of the fourth insulating interlayer 194 on the second region A2.

Next, the fourth insulating interlayer 194 on the first region A1 may be etched using the first etching mask pattern 196. Subsequently, the first capping layer pattern 132a (referred to FIG. 23), the second capping layer pattern 140a (referred to FIG. 23) and the third capping layer pattern 150a (referred to FIG. 23) may be sequentially etched to form first openings 198 in the fourth insulating interlayer 194. The first openings 198 may expose the upper surfaces of the first conductive patterns 122a, and may extend in the first direction X.

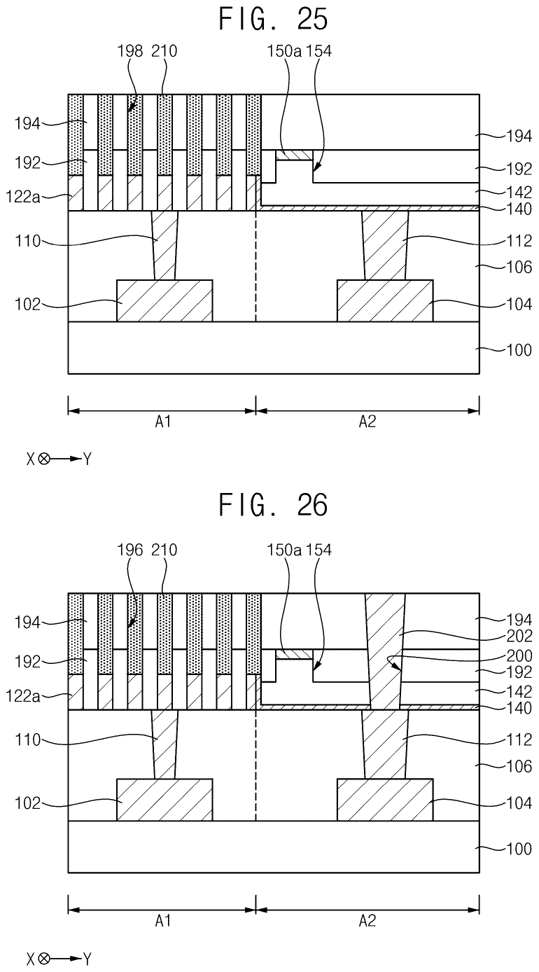

Referring to FIG. 25, a memory layer may be formed on the fourth insulating interlayer 194 to fill the first openings 198. Thereafter, the memory layer may be planarized until the upper surface of the fourth insulating interlayer 194 is exposed to form a preliminary memory pattern 210 in each of the first openings 198. In the planarization process, the first etching mask pattern 196 may be removed.

In example embodiments, the preliminary memory pattern 210 may include an ovonic threshold switch (OTS) material. The OTS material may include a chalcogen material such as S, Se, or Te. The OTS material may be the chalcogenide material mixed with materials such as Zn, As, Si, or Ge.

In example embodiments, the OTS material may include GeSe, GeS, AsSe, AsTe, AsS SiTe, SiSe, SiS, GeAs, SiAs, SnSe, SnTe, GeAsTe, GeAsSe, AlAsTe, AlAsSe, SiAsSe, SiAsTe, GeSeTe, GeSeSb, GaAsSe, GaAsTe, InAsSe, InAsTe, SnAsSe, SnAsTe, GeSiAsTe, GeSiAsSe, GeSiSeTe, GeSeTeSb, GeSiSeSb, GeSiTeSb, GeSeTeBi, GeSiSeBi, GeSiTeBi, GeAsSeSb, GeAsTeSb, GeAsTeBi, GeAsSeBi, GeAsSeIn, GeAsSeGa, GeAsSeAl, GeAsSeTl, GeAsSeSn, GeAsSeZn, GeAsTeIn, GeAsTeGa, GeAsTeAl, GeAsTeTl, GeAsTeSn, GeAsTeZn, etc. However, the OTS material is not limited to the above material. For example, the OTS material may include a material further doped with B, C, N, and/or O in the above material. Furthermore, the OTS material may include a five-component material or a six-component material manufactured by combining elements included in the above materials.

The lower surface of the preliminary memory pattern 210 may contact the first conductive pattern 122a. The first conductive pattern 122a may serve as a word line.

Referring to FIG. 26, a second etching mask pattern may be formed on the fourth insulating interlayer 194. The second etching mask pattern may cover entire upper surfaces of the fourth insulating interlayer 194 and the preliminary memory pattern 210 on the first region A1. Additionally, the second etching mask pattern may be positioned on the fourth insulating interlayer on the second region A2 to selectively expose a portion overlapping with the upper surface of the second lower contact 112.

The fourth insulating interlayer 194, the third insulating interlayer 192, the second insulating interlayer 142 and the second capping layer 140 on the second region A2 may be sequentially etched using the second etching mask pattern as an etching mask to form an upper contact hole 200. The upper contact hole 200 may exposes at least a portion of the upper surface of the second lower contact 112. Thereafter, the second etching mask pattern may be removed.

A third conductive layer may be formed on the fourth insulating interlayer 194 to fill the upper contact hole 200, and a planarization process may be performed until the upper surface of the fourth insulating interlayer 194 may be exposed to form an upper contact 202 in the upper contact hole 200. A bottom surface of the upper contact 202 may be disposed on a top surface of the second lower contact 112.

The bottom surface of the upper contact 202 may contact at least a portion of the top surface of the second lower contact 112. In example embodiments, an entire bottom surface of the upper contact 202 may contact the top surface of the second lower contact 112.

An uppermost surface of the second lower contact 112 may be substantially coplanar with a bottom surface of the second capping layer 140. That is, the uppermost surface of the second lower contact 112 may not be positioned lower than the bottom surface of the second capping layer 140. In example embodiments, the lowermost surface of the upper contact 202 may be substantially coplanar with the bottom surface of the second capping layer 140.

During the processes before forming the upper contact 202, the second lower contact 112 may not be removed due to the second capping layer 140. The second lower contact 112 may be substantially coplanar with the uppermost surface of the first insulating interlayer 106 adjacent to the second lower contact 112. The uppermost surface of the second lower contact 112 may not be positioned lower than the uppermost surface of the first insulating interlayer 106 on the first region A1. That is, the uppermost surface of the second lower contact 112 may be coplanar with or higher than the uppermost surface of the first insulating interlayer 106 of the first region A1. Since the upper surface of the second lower contact 112 has a sufficiently high vertical level, the upper contact 202 may have a target vertical height. Accordingly, a contacting failure between the upper contact 202 and the second lower contact 112 may be decreased.

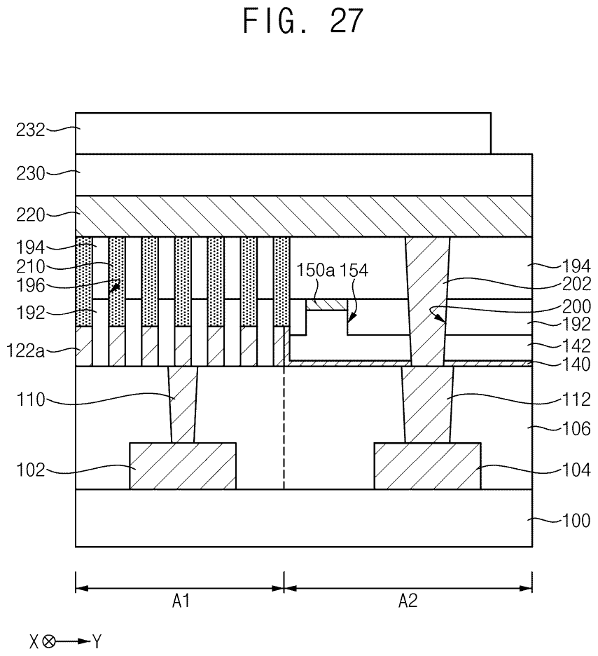

Referring to FIGS. 27 and 28, a fifth conductive layer 220 may be formed on the fourth insulating interlayer 194, the preliminary memory pattern 210 and the upper contact 202. A fourth capping layer 230 may be formed on the fifth conductive layer 220.

A third etching mask pattern 232 may be formed on the fourth capping layer 230. The third etching mask pattern 232 may have a line shape extending from the first region A1 to the second region A2 in the second direction Y The third etching mask pattern 232 may cover a portion of the preliminary memory pattern 210 and the upper contact 202.

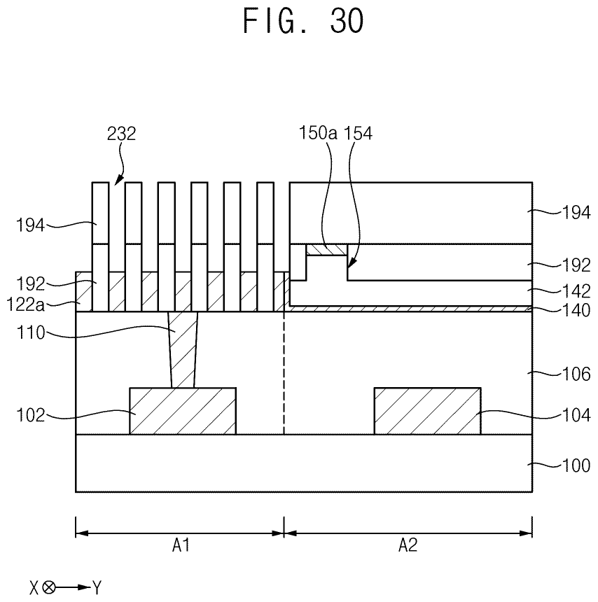

Referring to FIGS. 29 and 30, the fourth capping layer 230 and the fifth conductive layer 220 may be sequentially etched using the third etching mask pattern 232 (referred to FIG. 33), and then the preliminary memory pattern 210 may be etched. Accordingly, the fifth conductive layer 220 and the fourth capping layer 230 may be patterned to form upper wiring structures 234 in which the second conductive pattern 220a and the fourth capping layer pattern 230a are stacked. Additionally, the preliminary memory pattern 210 may be patterned to form a memory pattern 210a.

The upper wiring structures 234 may have a line shape extending in the second direction. The upper wiring structures 234 may be spaced apart from each other in the first direction. In example embodiments, the second conductive pattern 220a may serve as a bit line.

A bottom surface of the second conductive pattern 220a may contact the memory pattern 210a. The second conductive pattern 220a may extend from the first region A1 to the second region A2, and the bottom surface of the second conductive pattern 220a may contact the top surface of the upper contact 202. Accordingly, the upper contact 202 may be electrically connected to the second conductive pattern 220a.

The preliminary memory pattern 210 having a line shape may be cut in second direction Y to form memory patterns 210a. Thus, each of the memory patterns 210a may have an island shape. The memory patterns 210a may be positioned at cross points of the first conductive pattern 122a and the second conductive pattern 220a, respectively. A stacked structure of the first conductive pattern 122a, the memory pattern 210a and the second conductive pattern 220a may serve as a single memory cell.

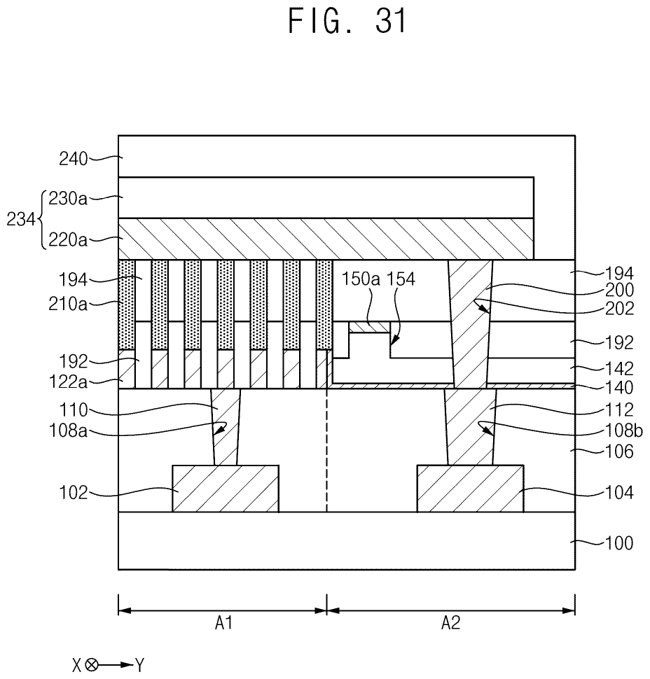

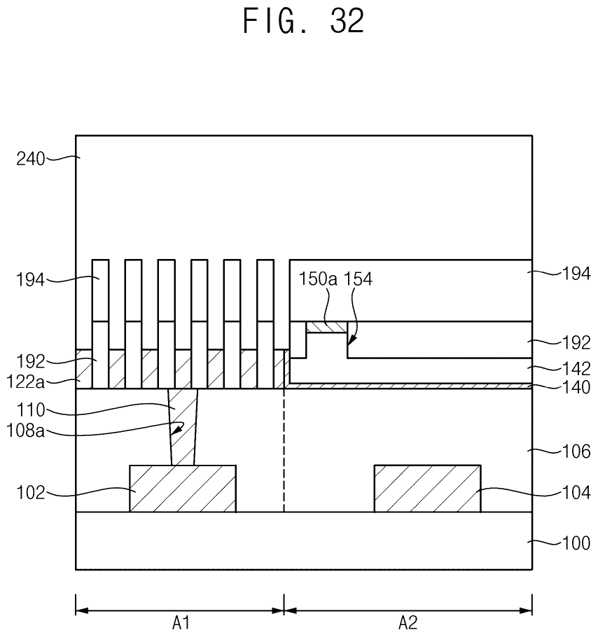

Referring to FIGS. 31 and 32, a fifth insulating interlayer 240 covering the upper wiring structure 234 may be formed on the fourth insulating interlayer 194. The fifth insulating interlayer 240 may fill a gap between the memory patterns 210a.

By performing the above processes, the memory cells including the first conductive pattern 122a and the second conductive pattern 220a may be formed on the first region A1 of the substrate 100, and the upper contact 202 having an upper surface higher than at least the first conductive pattern 122a and extending downward to contact the upper surface of the second lower contact 112 may be formed on the second region A2 of the substrate 100.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of the present inventive concept.

What is claimed is:

1. A semiconductor device, comprising:
a substrate including a first region and a second region;
a first insulating interlayer on the first region and the second region of the substrate;
a lower contact disposed on the second region of the substrate, the lower contact passing through the first insulating interlayer;
a wiring structure disposed on the first insulating interlayer on the first region, the wiring structure including a first conductive pattern;
a first capping layer covering an entire upper surface of the first insulating interlayer on the second region;
a second insulating interlayer disposed on the first capping layer on the second region, the second insulating interlayer having a protrusion positioned on the first capping layer at an edge of the second region adjacent to the first region;
a second capping layer pattern on an upper surface of the protrusion of the second insulating interlayer;
a third insulating interlayer covering the first insulating interlayer, the wiring structure, the second capping layer pattern and the second insulating interlayer, and the third insulating interlayer having an upper surface higher than an upper surface of the second capping layer pattern; and
an upper contact passing through the third insulating interlayer, the second insulating interlayer and the first capping layer on the second region, the upper contact contacting at least a portion of an upper surface of the lower contact.

2. The semiconductor device of claim 1, wherein the upper surface of the second capping layer pattern is positioned higher than an upper surface of the first conductive pattern.

3. The semiconductor device of claim 1, wherein the wiring structure includes a capping layer structure, and the capping layer structure includes a same material as the first capping layer and a same material as the second capping layer pattern.

4. The semiconductor device of claim 1, wherein the second capping layer pattern is further disposed on an uppermost portion of the wiring structure.

5. The semiconductor device of claim 4, further comprising a first capping layer pattern contacting a lower surface of the second capping layer pattern include in the wiring structure, and the first capping layer pattern having a material the same as a material of the first capping layer.

6. The semiconductor device of claim 1, wherein an uppermost surface of the lower contact is coplanar with a bottom surface of the first capping layer on the second region.

7. The semiconductor device of claim 1, wherein the wiring structure has a line shape extending in a first direction, and a plurality of wiring structures are spaced apart from each other in a second direction perpendicular to the first direction.

8. The semiconductor device of claim 1, wherein an uppermost surface of the wiring structure is coplanar with the upper surface of the second capping layer pattern on the upper surface of the protrusion of the second insulating interlayer.

9. A semiconductor device, comprising:
a substrate including a first region and a second region;
a first insulating interlayer disposed on the first region and the second region of the substrate;
a first lower contact passing through the first insulating interlayer on the first region;
a second lower contact passing through the first insulating interlayer on the second region;
wiring structures disposed on the first insulating interlayer of the first region, the wiring structures including a first conductive pattern, a first capping layer pattern, a second capping layer pattern and a third capping layer pattern;
a second capping layer covering an entire upper surface of the first insulating interlayer of the second region;
a second insulating interlayer disposed on the second capping layer on the second region, the second insulating interlayer having a protrusion positioned on the second capping layer at an edge of the second region adjacent to the first region;
a third capping layer pattern on an upper surface of the protrusion of the second insulating interlayer;
a third insulating interlayer disposed on the first insulating interlayer, the wiring structures, the third capping layer pattern and the second insulating interlayer, and the third insulating interlayer having an upper surface higher than upper surfaces of the wiring structures; and
an upper contact passing through the third insulating interlayer, the second insulating interlayer and the second capping layer on the second region, and the upper contact contacting at least a portion of an upper surface of the second lower contact.

10. The semiconductor device of claim 9, wherein the third capping layer pattern included in the wiring structures and the third capping layer pattern on the upper surface of the protrusion of the second insulating interlayer are coplanar with each other.

11. The semiconductor device of claim 9, wherein the second capping layer pattern included in the wiring structures and the second capping layer disposed on the second region include a same material.

12. The semiconductor device of claim 9, wherein an uppermost surface of the second lower contact is coplanar with a bottom surface of the second capping layer.

13. A semiconductor device, comprising:
a substrate including a first region and a second region;
a first insulating interlayer on the first region and the second region of the substrate;
a lower contact passing through the first insulating interlayer on the second region;
a plurality of first conductive patterns disposed on the first insulating interlayer of the first region, each of the plurality of first conductive patterns having a line shape extending in a first direction;
memory patterns being spaced apart from each other on each of the first conductive patterns;
a first capping layer covering an entire upper surface of the first insulating interlayer on the second region;
a second insulating interlayer disposed on the first capping layer on the second region, the second insulating interlayer having a protrusion on the first capping layer at an edge of the second region adjacent to the first region;
a second capping layer pattern on an upper surface of the protrusion of the second insulating interlayer;
a third insulating interlayer on the first insulating interlayer and the second insulating interlayer to fill a space between the plurality of first conductive patterns and the memory patterns;
an upper contact passing through the third insulating interlayer, the second insulating interlayer and the first capping layer on the second region, and at least a portion of the upper contact contacting an upper surface of the lower contact; and
a second conductive pattern disposed on the memory patterns, the upper contact and the third insulating interlayer, the second conductive pattern contacting the memory patterns and the upper contact.

14. The semiconductor device of claim 13, wherein the second capping layer pattern is positioned higher than an upper surface of the first conductive pattern, and the second capping layer pattern is positioned lower than a lower surface of the second conductive pattern.

15. The semiconductor device of claim 13, wherein each of the memory patterns include an OTS material.

16. The semiconductor device of claim 13, wherein the first capping layer and the second capping layer pattern include silicon nitride.

17. The semiconductor device of claim 13, wherein bottom surfaces of the plurality of first conductive pattern and a bottom surface of the first capping layer are coplanar with each other.

18. The semiconductor device of claim 13, wherein an uppermost surface of the lower contact is coplanar with or higher than an uppermost surface of the first insulating interlayer on the first region.

19. The semiconductor device of claim 13, wherein the second conductive pattern has a line shape extending from the first region to the second region in a second direction perpendicular to the first direction.

20. The semiconductor device of claim 12, further comprising a second lower contact passing through the first insulating interlayer on the first region, and the second lower contact contacting a bottom surface of at least one of the first conductive patterns.
